(19) United States
(12) Patent Application Publication
(10) Pub. No.: US 2025/0359103 A1
(43) Pub. Date: Nov. 20, 2025

(54) SEMICONDUCTOR DEVICES AND METHODS OF FORMING THE SAME

(71) Applicant: Taiwan Semiconductor Manufacturing Co., Ltd., Hsinchu (TW)

(72) Inventors: Chun-Ming Lung, Hsinchu (TW); Sung-En Lin, Xionglin Township (TW)

(21) Appl. No.: 19/261,008

(22) Filed: Jul. 7, 2025

Related U.S. Application Data
(63) Continuation of application No. 18/893,350, filed on Sep. 23, 2024.
(60) Provisional application No. 63/647,143, filed on May 14, 2024.

(51) Int. Cl. H10D 30/01; H10D 30/43; H10D 30/67; H10D 62/10; H10D 64/01

(52) U.S. Cl. CPC H10D 30/014; H10D 30/43; H10D 30/6735; H10D 30/6757; H10D 62/121; H10D 64/017

(57) ABSTRACT

A method includes forming a shallow trench isolation region aside of a protruding fin, and forming a composite hard mask over the shallow trench isolation region. The composite hard mask is formed through a plurality of deposition processes and a plurality of etching processes. The method further includes forming a dummy gate stack over the protruding fin, removing a sacrificial layer in the protruding fin to leave a space between a first and a second semiconductor nanostructures that are in the protruding fin, forming a disposable interposer in the space, removing the dummy gate stack, and removing the disposable interposer using an etching chemical. When the disposable interposer is removed, the composite hard mask is exposed to the etching chemical, and a bottom portion of the composite hard mask remains after the disposable interposer is removed. A gate stack is then formed to fill the space.

### PRIORITY CLAIM AND CROSS-REFERENCE

This application is a continuation of U.S. patent application Ser. No. 18/893,350, filed on Sep. 23, 2024, which application claims the benefit of the following provisionally filed U.S. Patent application: Application No. 63/647,143, filed on May 14, 2024, and entitled “SEMICONDUCTOR DEVICE AND FORMATION METHOD THEREOF,” which applications are hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3A, 3B, FIGS. 4-8 and FIGS. 21 through FIGS. 29A, 29B, 29C, and 29D illustrate the views of intermediate stages in the formation of transistors in accordance with some embodiments.

FIGS. 9-20 illustrate the views of intermediate stages in the formation of hard masks over STI regions in accordance with some embodiments.

FIG. 30 illustrates the difference of incubation time of silicon nitride in accordance with some embodiments.

FIG. 31 illustrates a process flow for forming transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate-All-Around (GAA) transistor and the method of forming the same are provided. In accordance with some embodiments of the present disclosure, a hard mask is formed over a Shallow Trench Isolation (STI) region to protect the STI region in the subsequent removal of disposable interposers. The hard mask may have a composite structure including a plurality of portions.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

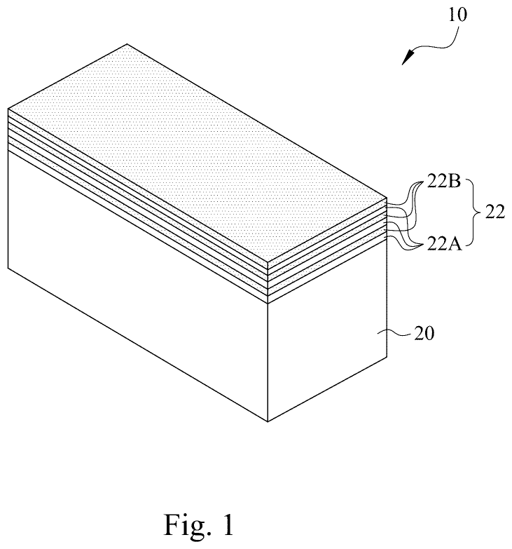

FIGS. 1 through 8 and FIGS. 21 through FIGS. 29A, 29B, 29C, and 29D illustrate the views of intermediate stages in the formation of a GAA transistor in accordance with some embodiments of the present disclosure. The corresponding processes are also reflected schematically in the process flow 200 as shown in FIG. 31.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

In accordance with some embodiments, multilayer stack 22 is formed through a series of deposition processes for depositing alternating materials. The respective process is illustrated as process 202 in the process flow 200 as shown in FIG. 31. In accordance with some embodiments, multilayer stack 22 comprises first layers 22A formed of a first semiconductor material and second layers 22B formed of a second semiconductor material different from the first semiconductor material.

In accordance with some embodiments, the first layers 22A are formed of or comprise a first semiconductor material such as SiGe, Ge, Si, GaAs, InSb, GaSb, InAlAs, InGaAs, GaSbP, GaAsSb, or the like. In accordance with some embodiments, the deposition of the first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like.

The second layers 22B are formed of or comprise a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of the first layers 22A. For example, in accordance with some embodiments in which the first layers 22A comprise silicon germanium, the second layers 22B may be formed of silicon, or vice versa. It is appreciated that any suitable combination of materials may be utilized for the formation of first layers 22A and the second layers 22B.

In accordance with some embodiments, the second layers 22B are epitaxially grown on the first layer 22A using a deposition technique similar to that is used to form the first layers 22A. The deposition process for forming alternating first layers 22A and second layers 22B is repeated to form the remaining layers in multilayer stack 22, until a desired topmost layer of multilayer stack 22 has been formed.

In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A will be removed in the subsequent processes, and are alternatively referred to as sacrificial layers 22A throughout the description.

In accordance with some embodiments, there may be some pad oxide layer(s) and hard mask layer(s) (not shown) formed over multilayer stack 22. These layers are patterned, and are used for the subsequent patterning of multilayer stack 22.

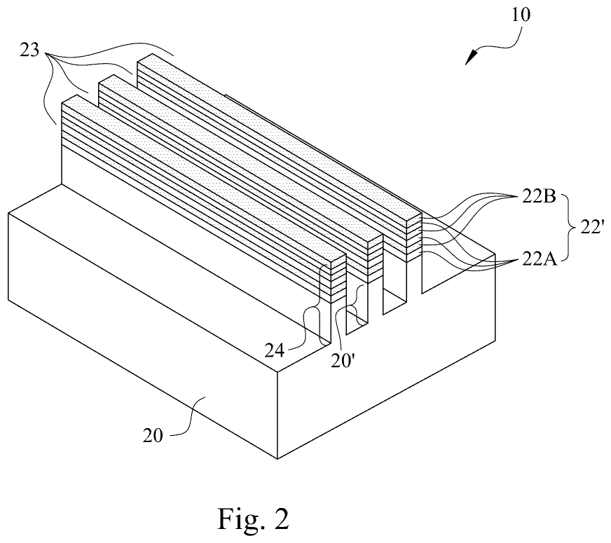

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 31. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

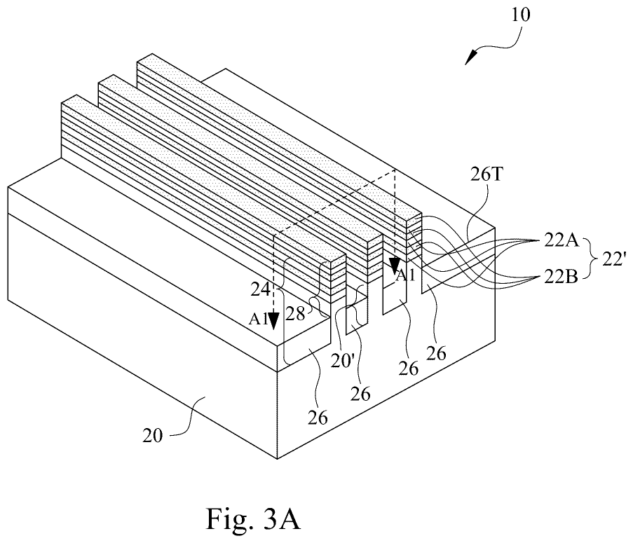

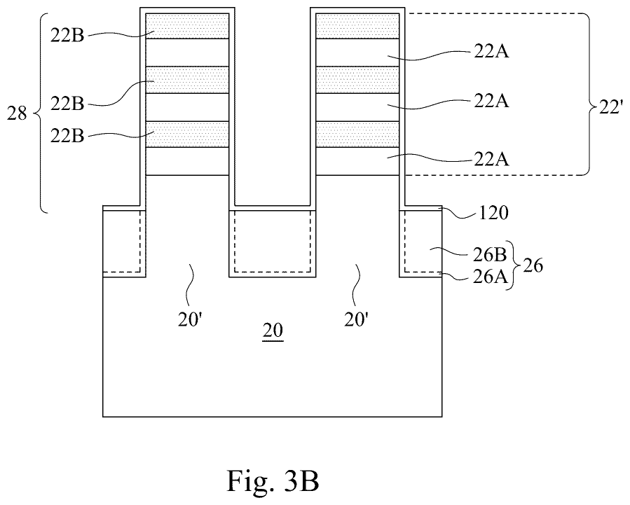

FIG. 3A illustrates the formation of isolation regions 26, which are also referred to as Shallow Trench Isolation (STI) regions throughout the description. The respective process is illustrated as process 206 in the process flow 200 as shown in FIG. 31. STI regions 26 may include a liner oxide (not shown), which may be a thermal oxide formed through the thermal oxidation of a surface layer of substrate 20, or may be deposited. The liner oxide may also be a deposited silicon oxide layer formed using, for example, ALD, High-Density Plasma Chemical Vapor Deposition (HDPCVD), CVD, or the like.

STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

FIG. 3B illustrates a cross-section A1-A1 in FIG. 3A. As shown in FIG. 3B, STI regions 26 may include dielectric liner 26A, and dielectric region 26B on dielectric liner 26A. Dielectric liner 26A and dielectric region 26B may be formed of different dielectric materials or a same dielectric material. For example, dielectric liner 26A may be formed of silicon nitride or silicon oxide, while dielectric region 26B may be formed of silicon oxide or silicon nitride.

Dielectric liner 26A and dielectric region 26B may also be formed of a same dielectric material such as silicon oxide, but have different properties. For example, dielectric region 26B may have a lower density and a higher etching rate than dielectric liner 26A. In accordance with alternative embodiments, the entireties of STI regions 26 are formed of a homogeneous material such as silicon oxide. In subsequent figures, dielectric liner 26A and dielectric region 26B are not shown separately.

FIGS. 3B through 8 illustrate the formation of hard masks in accordance with some embodiments. Further referring to FIG. 3B, dielectric layer 120 is formed. The respective process is illustrated as process 208 in the process flow 200 as shown in FIG. 31. In accordance with some embodiments, dielectric layer 120 comprises silicon oxide. The thickness of dielectric layer 120 may be in the range between about 120 Å and about 124 Å. The formation may include a deposition process, which may be a conformal deposition process such as ALD, CVD, or the like.

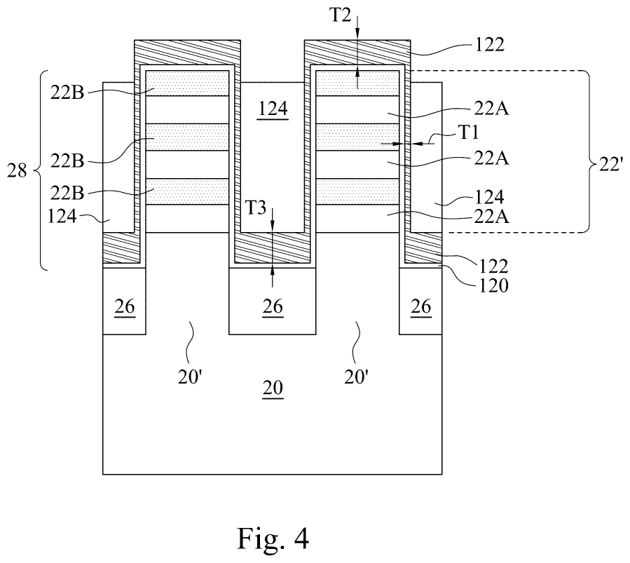

FIG. 4 illustrates the deposition of hard mask layer 122 (also referred to as protection layer 122). The respective process is illustrated as process 210 in the process flow 200 as shown in FIG. 31. The formation of hard mask layer 122 may include Plasma Enhanced Chemical Vapor Deposition (PECVD), Plasma Enhanced Atomic Layer Deposition (PEALD), or the like. In accordance with some embodiments, hard mask layer 122 is formed as a non-conformal layer, which has sidewall portions having thickness T1, top portions having thickness T2, and bottom portions having thickness T3. The thicknesses T2 and T3 are greater than thickness T1. For example, the ratios T2/T1 and T3/T1 may be in the range between about 3 and about 20. The formation of the non-conformal hard mask layer 122 may be achieved, for example, by applying a bias power during the deposition of hard mask layer 122.

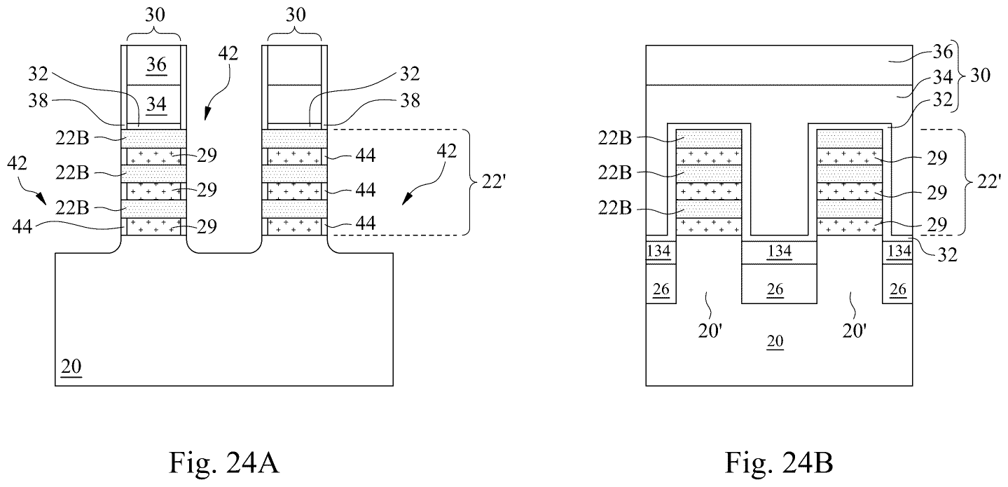

Hard mask layer 122 is formed of a dielectric material that is different from (and having high etching selectivity relative to) the dielectric material of the underlying STI regions 26. The material of hard mask layer 122 may also be different from (and having high etching selectivity relative to) the material of the subsequently formed disposable interposers 29 (FIGS. 24A and 24B). The etching selectivity may be higher than about 10, and may be in the range between about 10 and 100, for example.

In accordance with some embodiments, hard mask layer 122 may be formed of or comprises a silicon-and-nitrogen containing dielectric material and/or a silicon-and-carbon containing dielectric material such as SIN, SiCN, SiON, SiCON, SiC, SiOC, or the like. Hard mask layer 122 may also comprise a high-k dielectric material such as Al₂O₃ (ALD), HfO₂, HfSiO, ZrO₂, La₂O₃, Y₂O₃, or the like, or combinations thereof.

FIG. 4 further illustrates the formation of sacrificial layer 124, which is used as an etching mask. In accordance with some embodiments, sacrificial layer 124 includes a material that may be used as a Bottom Anti-Reflective Coating (BARC), and may include a cross-linked photoresist, SiOC, or the like. The formation of sacrificial layer 124 may include a deposition (or dispensing) process, followed by a planarization process, and then an etch-back process. The top portions of the hard mask layer 122 are thus exposed. The thickness T4 of sacrificial layer 124 may be in the range between about 50 Å and about 200 Å.

An etching process is then performed to remove some top portions and sidewall portions of the hard mask layer 122. The respective process is illustrated as process 212 in the process flow 200 as shown in FIG. 31. The etching chemical is selected to have a low etching rate on dielectric layer 120, and dielectric layer 120 is used as an etch stop layer. The etching may be performed through a dry etching process, a wet etching process, or the like.

In accordance with some embodiments, the etching gas may include a fluorine-containing gas such as CF₄, NF₃, SF₆, CHF₃, CIF₃, or the like, or combinations thereof. Other gases such as O₂, N₂, H₂, Ar, NO, and the like, may also be added. In accordance with alternative embodiments, a wet etching process may be adopted, for example, using H₃PO₄. After the etching process, the top portion of the hard mask layer 122 may be fully removed to expose dielectric layer 120, or may have a thin portion remaining.

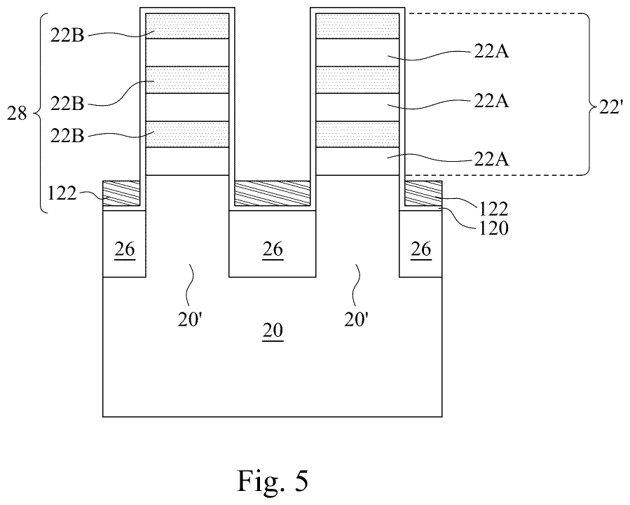

The sacrificial layer 124 is then removed, followed by an etching process to remove the top portions (when remaining) and sidewalls portions of hard mask layer 122. The resulting structure is shown in FIG. 5. The remaining portions of hard mask layer 122 are referred to as hard masks 122′ (alternatively referred to as hard mask layers 122′). The top surfaces of hard masks 122′ may be level with or lower than the top surfaces of substrate strips 20′ so that hard masks 122′ do not adversely affect the removal of the sacrificial layers 22A in subsequent processes.

In accordance with alternative embodiments, the top surfaces of hard masks 122′ may be higher than the top surfaces of substrate strips 20′ but lower than the top surfaces of the bottom ones of sacrificial layers 22A. The etching process may be isotropic, and may be performed through a dry etching process or a wet etching process, for example, using the aforementioned chemical that are used for removing the top portions of the hard mask layer 122. Dielectric layer 120 is used as an etch stop layer. In the etching of the hard mask layer 122, the etching process is controlled, so that the top portions and the sidewall portions of the hard mask layer 122 are fully removed, while the bottom portions have at least some portions remaining.

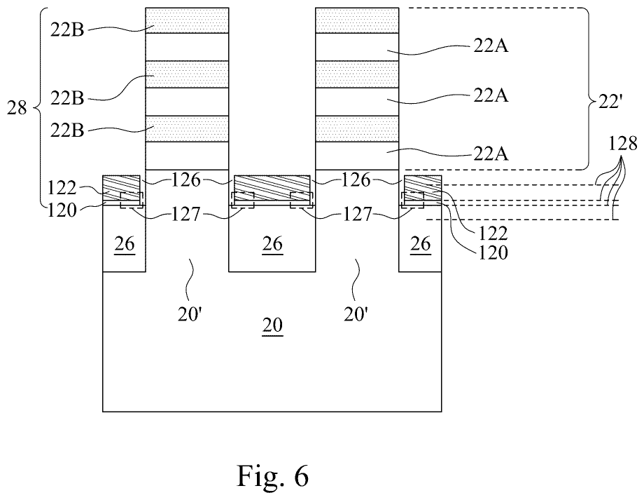

Next, the dielectric layer 120 is etched, exposing the protruding fins 28. The respective process is illustrated as process 214 in the process flow 200 as shown in FIG. 31. The resulting structure is shown in FIG. 6.

Due to the removal of dielectric layer 120, recesses 126 are formed, which are between protruding fins 28 and hard masks 122′. The bottoms of recesses 126 may be at any level lower than the top surfaces of hard masks 122′. For example, in FIG. 6, dashed lines 128 illustrate the possible positions of the bottoms of the recesses 126, which bottoms may be between the top surface and the bottom surface of hard masks 122′, level with the bottom surface of hard mask layer 122′, level with the top surfaces of STI regions 26, or lower than the top surfaces of STI regions 26 (when some edge portions of STI regions 26 are etched). In accordance with yet alternative embodiments, the portions of dielectric layer 120 in regions 127 may also be laterally recessed to form undercuts.

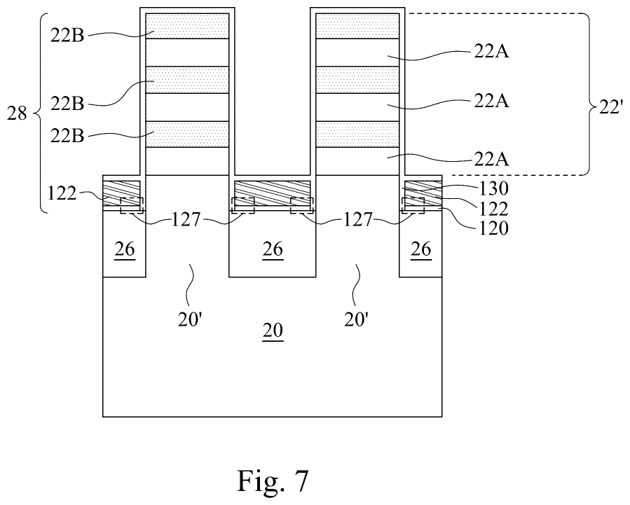

Referring to FIG. 7, a second hard mask layer 130 is deposited, which process is referred to as a hard mask re-deposition process since it is deposited to fill the recesses 126 that are not filled by hard masks 122′. The respective process is illustrated as process 216 in the process flow 200 as shown in FIG. 31.

The material of hard mask layer 130 may be selected from the same group of candidate materials of hard masks 122′, and may the same as or different from the material of hard masks 122′. When hard mask layer 130 is formed of the same material as hard masks 122′, the hard mask layer 130 may have a same density as, or a higher or lower density than, hard masks 122′. In accordance with some embodiments, the hard masks 122′comprises silicon nitride, and hard mask layer 130 may be formed of silicon nitride or other dielectric materials. In accordance with some embodiments, hard mask layer 130 may be distinguishable from hard masks 122′, for example, through Transmission Electron Microscopy (TEM). In accordance with other embodiments, hard mask layer 130 may not be distinguished from hard masks 122′.

In accordance with some embodiments, hard mask layer 130 may be deposited through PEALD, PECVD, CVD, ALD, or the like. Some of these methods such as PEALD have the advantageous feature of bottom-up growth, and thus may fill recesses 126 better without the formation of voids. In accordance with the embodiments in which the portions of dielectric layer 120 in regions 127 are laterally recessed to form undercuts, the undercuts may be fully filled with hard mask layer 130. In accordance with alternative embodiments, the undercuts in regions 127 are partially filled with hard mask layer 130. Accordingly, hard mask layer 130 includes some lateral portions in regions 127, which lateral portions are overlapped by hard masks 122′.

Voids (air spacers) are formed between the lateral portions of hard mask layer 130 and dielectric layer 120. In accordance with yet alternative embodiments, the undercuts in regions 127 are not filled with hard mask layer 130, and hence regions 127 are voids (air gaps).

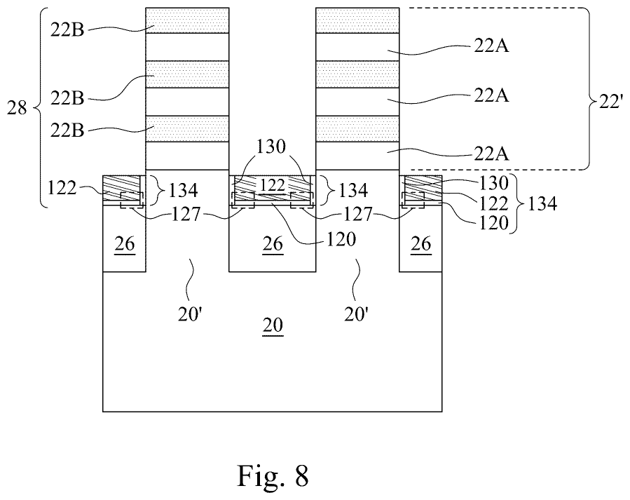

Referring to FIG. 8, an etching process is performed to etch the top portions and the sidewall portions of hard mask layer 130. The respective process is illustrated as process 218 in the process flow 200 as shown in FIG. 31. The etching may be through an isotropic etching process using an etching chemical that is selective to hard mask layer 130. For example, when hard mask layer 130 comprises SiN, H₃PO₄ solution may be used as the etchant. Nanostructures 22B and sacrificial layers 22A, on the other hand, are not etched.

In the resulting structure, the remaining portions of hard mask layer 130 fill the recesses 126 (FIG. 6). Hard masks (also referred to as hard mask layers) 122′ and 130 are collectively referred to as hard mask layer 134, which may or may not include the underlying dielectric layer 120, depending on their materials. The material of dielectric layer 120 may be the same as or different from, the material of STI regions 26. Dielectric layer 120 may be distinguishable from (for example, with different materials and/or different densities) STI regions 26. The material of hard mask layer 130 may be the same as or different from, the material of hard masks 122′. Hard mask layer 130 may be distinguishable from (for example, with different materials and/or different densities of the same material) hard masks 122′.

In accordance with some embodiments, regions 127 may include portions of the hard masks 130. In accordance with alternative embodiments, regions 127 may include voids (air gaps). In accordance with yet alternative embodiments, regions 127 may include some portions of hard masks 130 directly underlying hard mask layer 122′, and voids between hard masks 130 and the respective closest portions of dielectric layer 120.

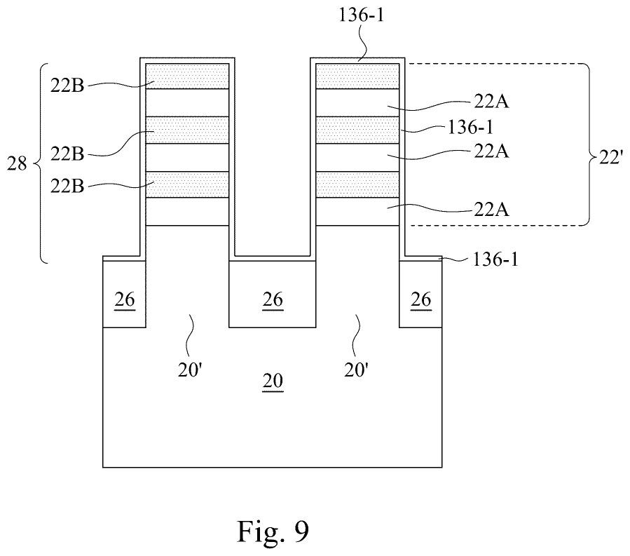

FIGS. 9 through 20 illustrate the formation of hard masks 134 in accordance with alternative embodiments. Referring to FIG. 9, dielectric layer 136-1 is deposited. The deposition may be achieved through a conformal deposition process such as ALD, CVD, or the like. Dielectric layer 136-1 may comprise an oxide such as silicon oxide (SiO₂), SiOC, or the like. The thickness of dielectric layer 136-1 is small, and may be in the range between about 0.5 nm and about 2 nm, for example.

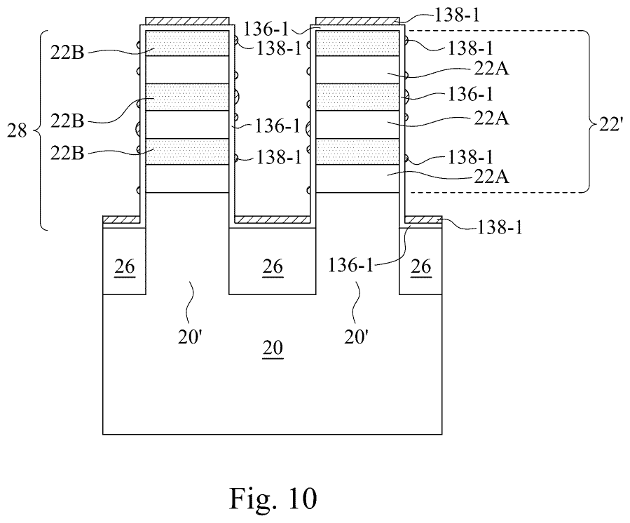

Referring to FIG. 10, hard mask layer 138-1 is deposited. The formation process may include PEALD or another applicable process. The hard mask layer 138-1 includes portions on tops of protruding fins 28, bottom portions at the bottoms of the trench between neighboring protruding fins 28, and may or may not include some discrete islands (as schematically illustrated) on the sidewall portions of dielectric layer 136-1. Hard mask layer 138-1 may comprise a nitrogen-containing material such as Si₃N₄, SiON, SiCN, or the like, in accordance with some embodiments.

In accordance with some embodiments, during the PEALD process, a bias power is applied to increase the thickness of the top portions and bottom portions of hard mask layer 138-1, and reduce (relatively) the sidewall portions of hard mask layer 138-1. The bias power is selected to be not too high and not too low. If the bias power is too high, there is significant bombardment effect, and the top portions and the bottom portions of hard mask layer 138-1 cannot be deposited. If the bias power is too low, the difference between the incubation time of the top and bottom portions and the incubation time of the sidewall portions is not high enough, as desirable for the subsequent process. In accordance with some embodiments, the bias power is in the range between about 80 watts and about 220 watts.

It is appreciated that some materials such as silicon nitride has high activation energy when grown on silicon oxide, and thus has long incubation time. Accordingly, the incubation time for hard mask layer 138-1 is long. In accordance with some embodiments, to reduce the incubation time for the top portions and the bottom portions, the bias power is applied to overcome the activation energy barrier. The bias power, however, does not affect the incubation time of the sidewall portions. The top portions and the bottom portions of the hard mask layer 138-1 thus are incubated earlier than the sidewall portions of hard mask layer 138-1.

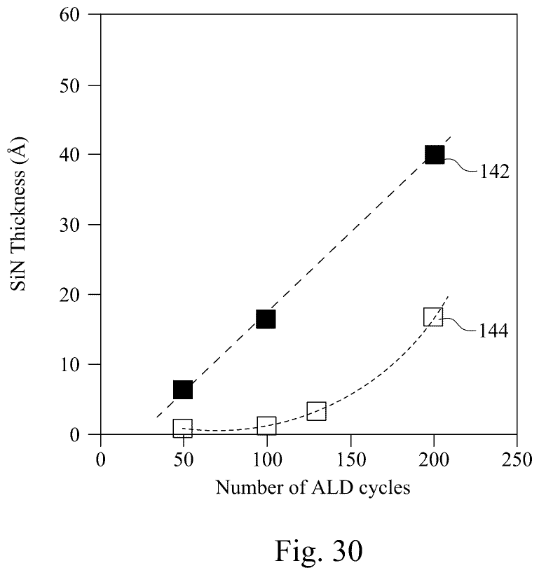

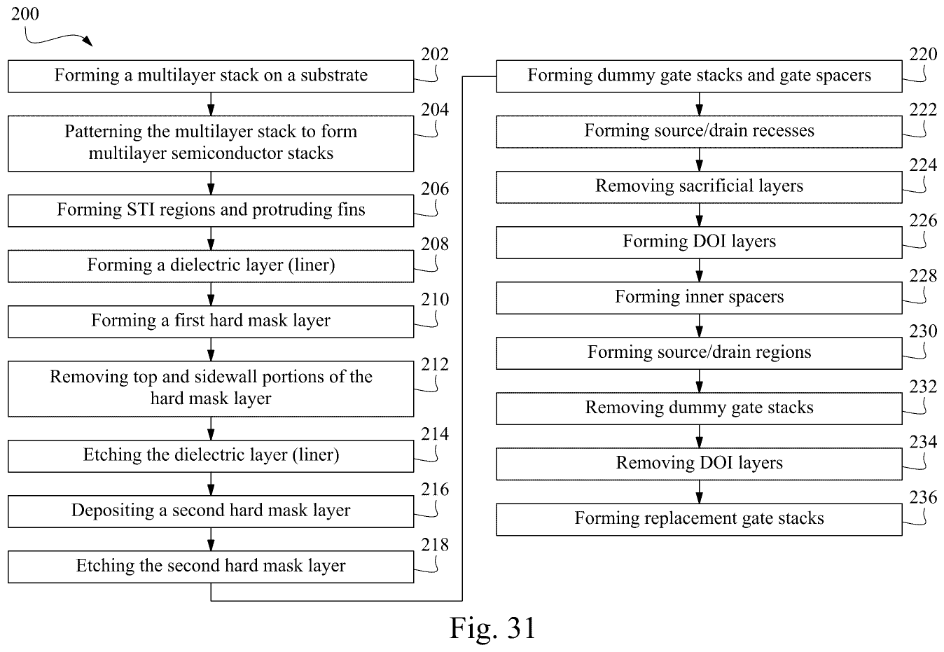

FIG. 30 illustrates the thickness of the grown SiN layer as a function of number of ALD cycles. Solid rectangles 142 represent the data obtained at the top and bottom portions of dielectric layer 136-1, which are at plasma-rich regions due to the bias power. Hollow rectangles 144 represent the data obtained on the sidewall portions of dielectric layer 136-1, which are at plasma-scarce regions. The data represented by solid rectangles 142 and hollow rectangles 144 indicate that the incubation of the top and bottom portions of hard mask layer 138-1 is much faster, and occurs earlier, than the sidewall portions of hard mask layer 138-1. Accordingly, the thickness of the top and bottom portions of hard mask layer 138-1 may increase linearly for a period of time, while the sidewall portions of hard mask layer 138-1 are still trying to incubate. In an example, when 100 ALD cycles are finished, the thicknesses of the top/bottom portions may be greater than 2 nm, while the sidewall portions of hard mask layer 138-1 are still trying to incubate.

Furthermore, other process conditions, such as source power, pressure, and the like in the deposition of hard mask layer 138-1 may be controlled to enlarge the difference between the incubation time of the top/bottom portions and the incubation time of the sidewall portions of hard mask layer 138-1.

In accordance with some embodiments, the deposition of the hard mask layer 138-1 is stopped when the top portions and the bottom portions of the hard mask layer 138-1 are grown as continuous layers. The thicknesses of the top portions and the bottom portions of the hard mask layer 138-1 may be in the range between about 1 nm and about 3 nm.

The deposition of the hard mask layer 138-1 is stopped before the sidewall portions of the hard mask layer 138-1 are grown as a continuous layer that covers the entire sidewall portions of dielectric layer 136-1. Furthermore, the coverage of the sidewall portions of the hard mask layer 138-1 is smaller than about 50 percent, may be smaller than about 30 percent, or smaller than about 10 percent.

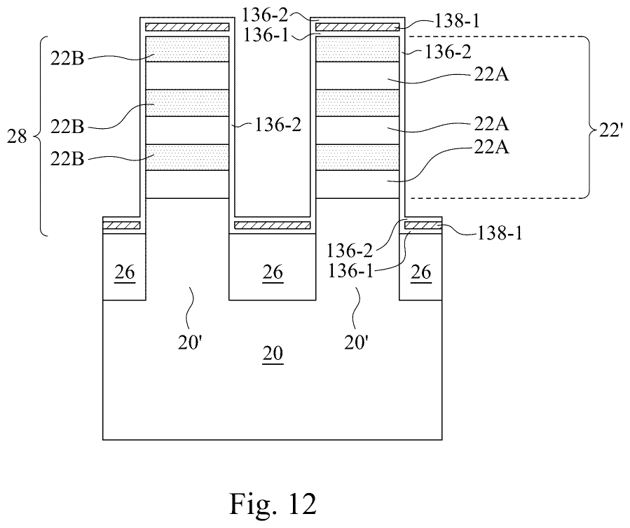

To increase the process efficiency, the deposition of the hard mask layer 138-1 is also as long as possible, with as much as ALD (such as PEALD) cycles as possible, so that the cycles as shown in FIGS. 12, 13, and 14 do not have to be repeated too many times. Accordingly, the deposition of the hard mask layer 138-1 may also be stopped when the coverage of the sidewall portions of the hard mask layer 138-1 is greater than about 1 percent or greater than about 5 percent. In accordance with alternative embodiments, the deposition of the hard mask layer 138-1 may also be stopped when no hard mask layer 138-1 is grown on the sidewall portions of dielectric layer 136-1 yet.

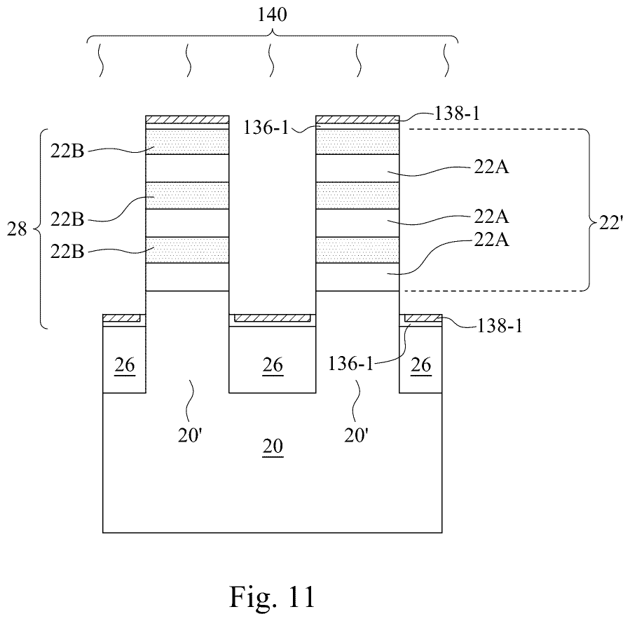

Next, as shown in FIG. 11, an etching process 140, which may be an isotropic etching process, is performed to remove the sidewall portions of dielectric layer 136-1. The isotropic etching process may be a dry etching process or a wet etching process. For example, when dry etching is used, a mixture of NF₃ and NH₃ or a mixture of HF and NH₃ may be used as the etching gas. When wet etching is performed, a diluted HF solution may be used as the etching solution.

As a result of the etching process 140, the sidewall portions of the dielectric layer 136-1 are removed. The top and bottom portions of dielectric layer 136-1, however, are protected by the top and bottom portions of hard mask layer 138-1, and are not removed. If hard mask layer 138-1 has any portions grown on the sidewall portions of dielectric layer 136-1, the corresponding sidewall portions are discrete islands, and will not prevent the removal of the sidewall portions of dielectric layer 136-1. As a result, the sidewall portions of hard mask layer 138-1 are removed (lifted) due to the removal of the sidewall portions of the dielectric layer 136-1.

The processes as shown in FIGS. 9-11 are collectively referred to as a first hard mask deposition-and-etch cycle. Due to the limit that the growth of dielectric hard mask layer 138-1 is stopped before full incubation occurs on the sidewall portions of dielectric layer 136-1, the thickness of the bottom portions of dielectric hard mask layer 138-1 is limited. More hard mask deposition-and-etch cycles thus may be performed to increase the thickness of hard mask layer 138 (which includes hard mask layer 138-1 and subsequent hard mask layers.). FIGS. 12-14 illustrate a second hard mask deposition-and-etch cycle in accordance with some embodiments. The processes, materials, and structures may be essentially the same as that in FIGS. 9-11.

Referring to FIG. 12, dielectric layer 136-2 is deposited. The material of dielectric layer 136-2 may be the same as or different from that of dielectric layer 136-1.

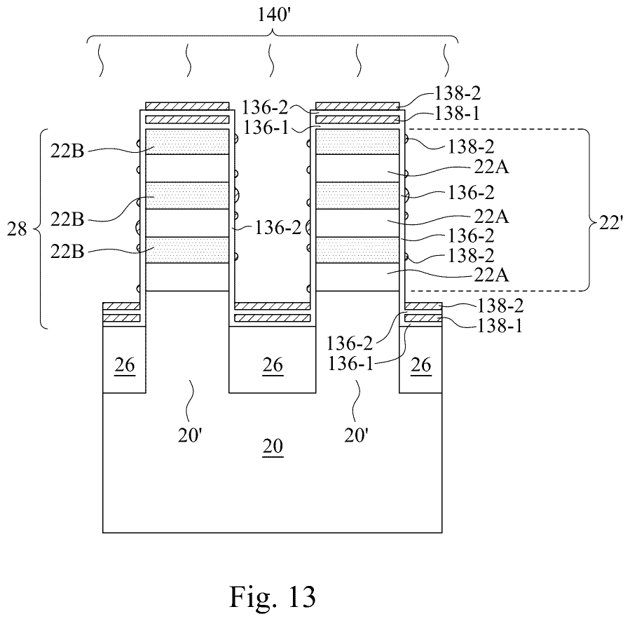

Next, as shown in FIG. 13, hard mask layer 138-2 is deposited. The material, the formation process, and the process conditions are essentially the same for the formation of hard mask layer 138-2, and are not repeated herein. The material of hard mask layer 138-2 may be the same or different from that of hard mask layer 138-1. On the sidewalls of dielectric layer 136-2, hard mask layer 138-2 is either not incubated (without being formed) or partially incubated, and may be formed as discrete islands.

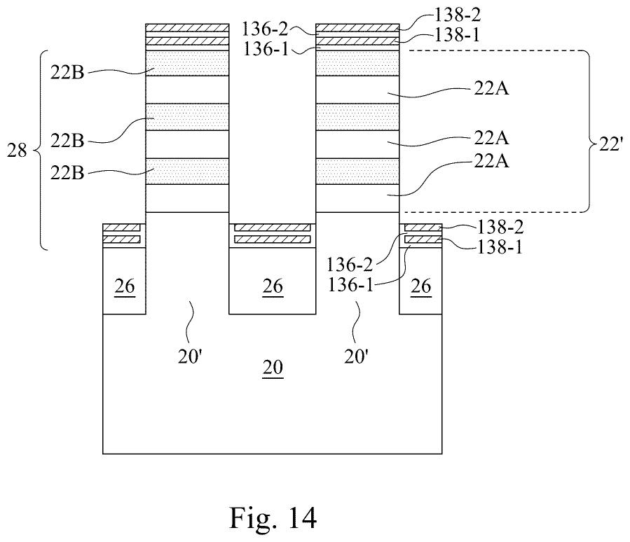

Next, an etching process 140′ is performed on dielectric layer 136-2. The sidewall portions of dielectric layer 136-2 and the portions (if any) of hard mask layer 138-2 on the sidewall portions of dielectric layer 136-2 are removed. The resulting structure is shown in FIG. 14.

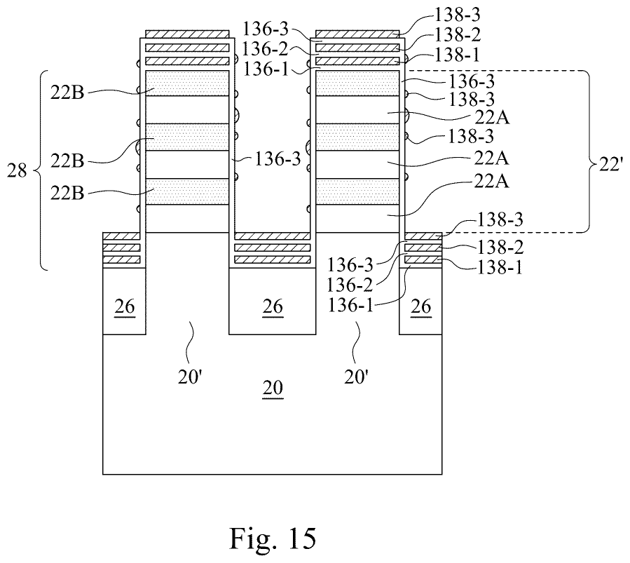

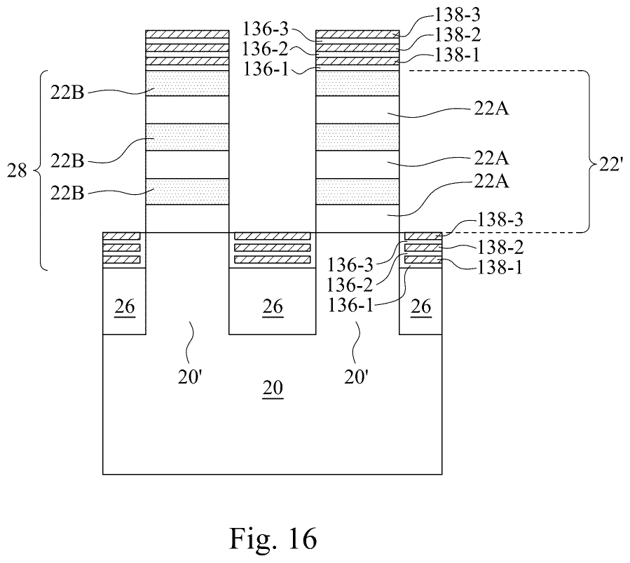

FIGS. 15 and 16 illustrate a third hard mask deposition-and-etch cycle, in which dielectric layer 136-3 and hard mask layer 138-3 are formed. As shown in FIG. 15, a blanket dielectric layer 136-3 is deposited using essentially the material and process as discussed for the formation of dielectric layer 136-1. Next, hard mask layer 138-3 is deposited. The material and process may be selected from the same candidate group of materials and processes as the formation of hard mask layer 138-1. Again, on the sidewall portions of dielectric layer 136-3, hard mask layer 138-3 may not be incubated or may be partially incubated, and may, or may not, include the deposited islands. FIG. 16 illustrates the etching of the sidewall portions of dielectric layer 136-3 and the sidewall portions of hard mask layer 138-3 (if any).

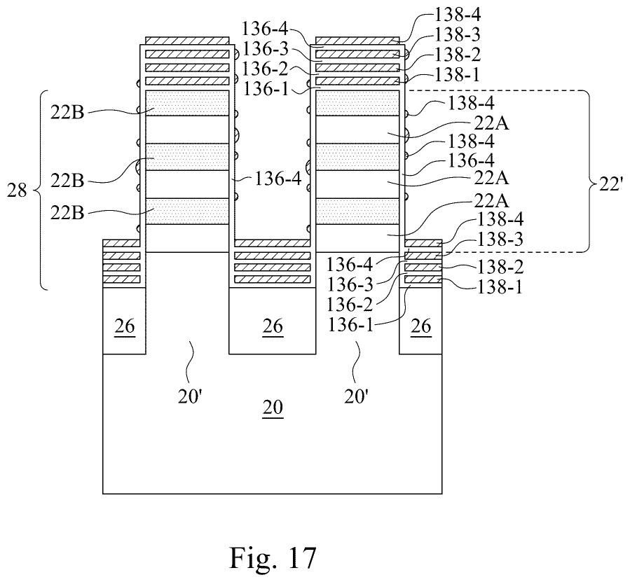

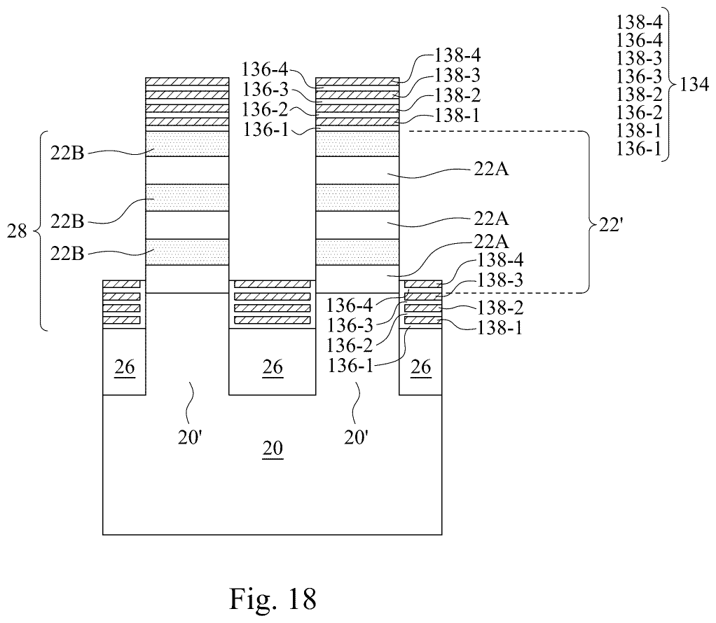

FIGS. 17 and 18 illustrate a fourth hard mask deposition-and-etch cycle, in which dielectric layer 136-4 and hard mask layer 138-4 are formed. The process details are essentially the same as described for the underlying layers, and are not repeated herein. In accordance with some embodiments, more deposition-and-etch cycles may be performed to add more hard mask layers and dielectric layers. Dielectric layers 136-1, 136-2, 136-3, and 138-4, and the like are individually and collectively referred to as dielectric layers 136. Hard mask layers 138-1, 138-2, 138-3, and 138-4 and the like are individually and collectively referred to as hard mask layers 138. Throughout the description, a dielectric layer 136 and its immediately overlying hard mask layer 138 are collectively referred to as a dual-layer hard mask layer 136/138. The plurality of dual-layer hard mask layers 136/138 collectively form composite hard mask 134.

In FIG. 18, the top surfaces of the top hard mask layers (such as top hard mask layers 138-4) may be level with or lower than the top surfaces of substrate strips 20′ so that composite hard mask 134 do not prevent the removal of sacrificial layer 22A in subsequent processes. In accordance with alternative embodiments, the top surfaces of top hard mask layers (such as top hard mask layers 138-4) may be higher than the top surfaces of substrate strips 20′ but lower than the top surfaces of the bottom ones of sacrificial layers 22A.

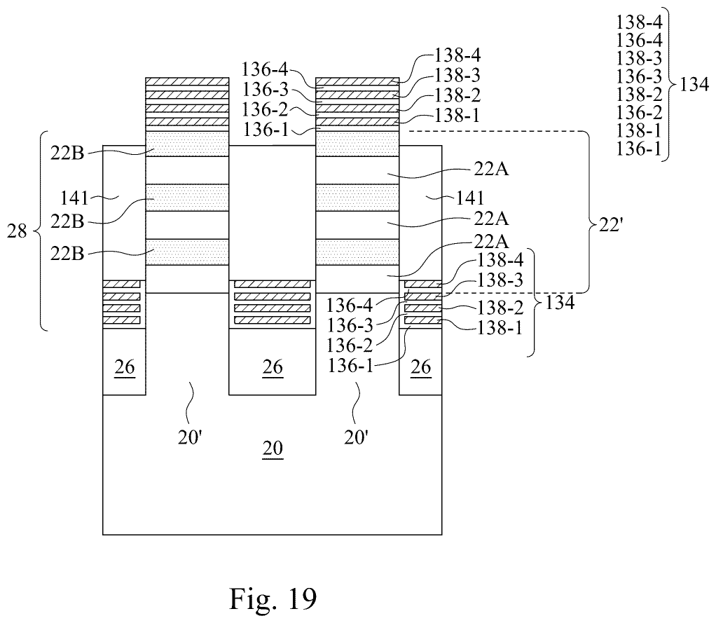

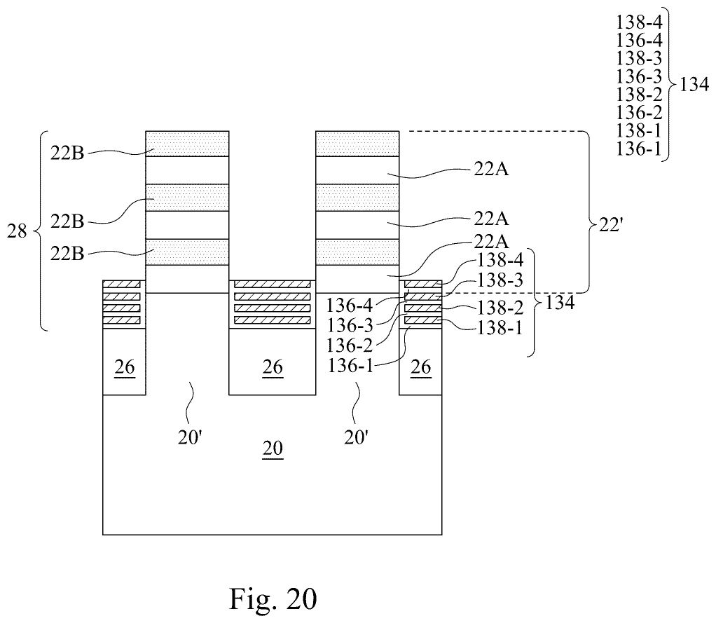

FIGS. 19 and 20 illustrate the removal of the top portions of composite hard mask 134. Referring to FIG. 19, sacrificial layer 141 is formed, which is used as an etching mask. In accordance with some embodiments, sacrificial layer 141 includes a material that may be used as a BARC, and may include a cross-linked photoresist, SiOC, or the like. The formation of sacrificial layer 141 may include a deposition (or dispensing) process, followed by a planarization process and an etch-back process. The top portions of composite hard mask 134 are thus exposed.

FIG. 20 illustrates an etching process to remove some top portion of the composite hard mask 134. The etching may include a plurality of first etching processes and a plurality of second etching processes performed alternatingly. The first etching processes are used to etch hard masks 138, and the second etching processes are used to etch dielectric layers 136. The etching may also be performed using an etching chemical that etches both of the dielectric layers 136 and hard masks 138. After the etching process, sacrificial layer 141 is removed, leaving the structure as shown in FIG. 20, in which the composite hard mask 134 includes a plurality of hard mask layers 138 and a plurality of dielectric layers 136.

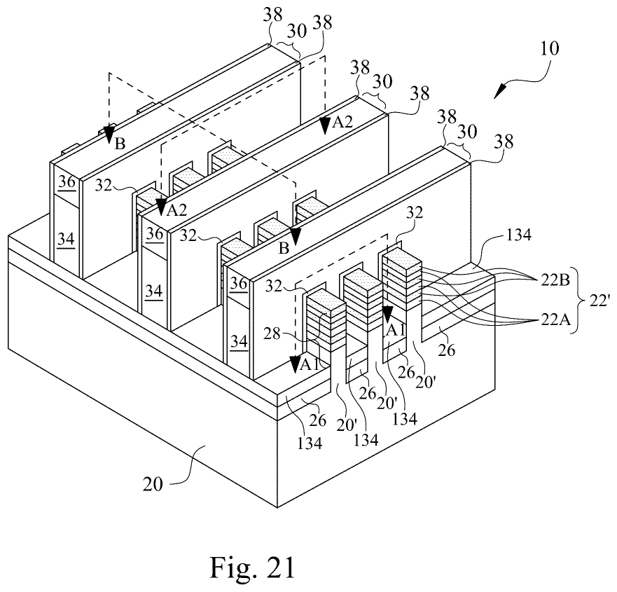

Referring to FIG. 21, which shows a perspective view, dummy gate stacks 30 and gate spacers 38 are formed on the top surfaces and the sidewalls of (protruding) fins 28. The respective process is illustrated as process 220 in the process flow 200 as shown in FIG. 31. The composite hard masks 134 as shown in FIG. 21 may have the structure as shown in FIG. 8 or the structure as shown FIG. 20. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask 36 over dummy gate electrode 34. Hard masks 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard masks, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

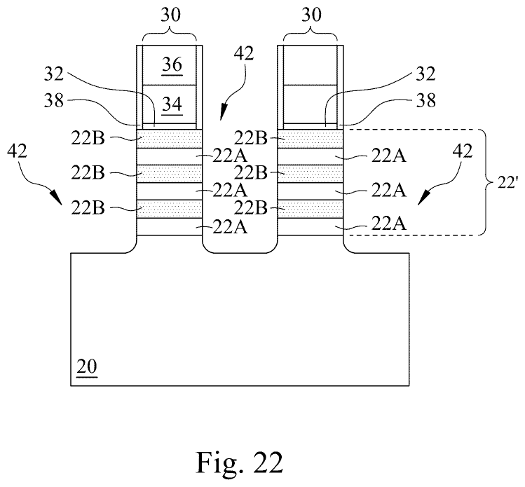

FIG. 22 illustrates the source/drain recessing process. The respective process is illustrated as process 222 in the process flow 200 as shown in FIG. 31. FIG. 22 illustrates the cross-section B-B as shown in FIG. 21. The protruding fins 28 that are not directly underlying dummy gate stacks 30 and gate spacers 38 are etched in an anisotropic etching process. Source/drain recesses 42 are thus formed, as shown in FIG. 22.

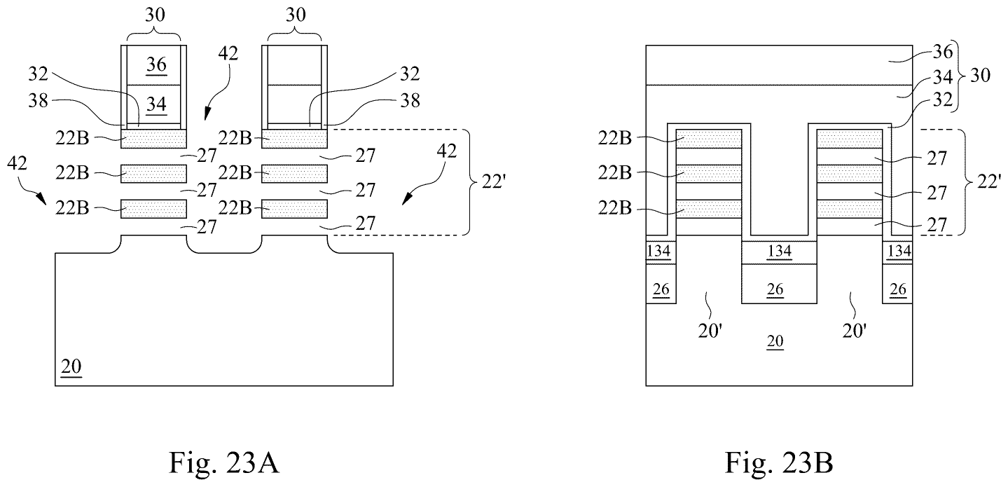

FIGS. 23A, 23B, 24A, and 24B illustrate the replacement of sacrificial layers 22A with disposable interposers 29. Referring to FIGS. 23A and 23B, which illustrate the cross-sections B-B and A2-A2, respectively in FIG. 21, the sacrificial layers 22A are first removed, forming openings 27 between nanostructures 22B. The respective process is illustrated as process 224 in the process flow 200 as shown in FIG. 31. The hard mask 134 as shown in FIG. 23B and subsequent figures may represent the hard mask 134 shown in FIG. 8 or the hard mask 134 shown in FIG. 20 in accordance with various embodiments.

Referring to FIGS. 24A and 24B, disposable interposers 29 are formed between nanostructures 22B. The respective process is illustrated as process 226 in the process flow 200 as shown in FIG. 31. In accordance with some embodiments, disposable interposers 29 comprise an oxide such as silicon oxide, and thus may also be referred to as Disposable Oxide Interposers (DOIs) 29. In accordance with other embodiments, other types of oxides may be adopted.

The formation of disposable interposers 29 may include depositing a dielectric layer using a conformal deposition process, so that the dielectric layer includes some portions filling openings 27, and some other portions outside of openings 27. A trimming process, which may include an isotropic etching process, is then performed to etch and remove the portions of the dielectric layer outside of openings 27. The remaining portions of the dielectric layer are thus the disposable interposers 29.

Disposable interposers 29 are then laterally recessed to form inner spacers 44 (FIG. 24A). The lateral recessing of disposable interposers 29 may be achieved through a wet etching process or a dry etching process. The wet etching process may be performed using a dip process, a spray process, a spin-on process, or the like. Nanostructures 22B are not etched.

Inner spacers 44 are then formed. The respective process is illustrated as process 228 in the process flow 200 as shown in FIG. 31. In accordance with some embodiments, the formation of inner spacers 44 includes depositing a conformal dielectric layer, which extends into the lateral recesses. Next, an etching process (also referred to as a spacer trimming process) is performed to trim the portions of the dielectric layer outside of the lateral recesses, leaving the portions of the dielectric layer in the lateral recesses. The remaining portions of the dielectric layer are referred to as inner spacers 44.

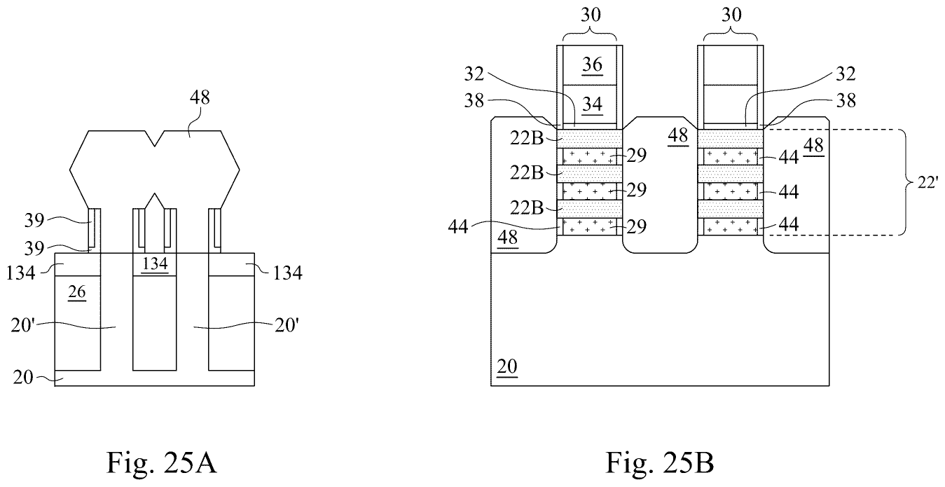

Referring to FIGS. 25A and 25B, which illustrate the same cross-section as the cross-sections A1-A1 and B-B, respectively in FIG. 21, epitaxial source/drain regions 48 are formed in recesses 42 through selective epitaxy. The respective process is illustrated as process 230 in the process flow 200 as shown in FIG. 31. Depending on whether the resulting transistor is a p-type transistor or an n-type transistor, a p-type or an n-type impurity may be in-situ doped with the proceeding of the epitaxy. For example, when the resulting transistor is a p-type Transistor, silicon germanium boron (SiGeB), silicon boron (SiB), or the like may be grown. Conversely, when the resulting transistor is an n-type Transistor, silicon phosphorous (SiP), silicon carbon phosphorous (SiCP), or the like may be grown.

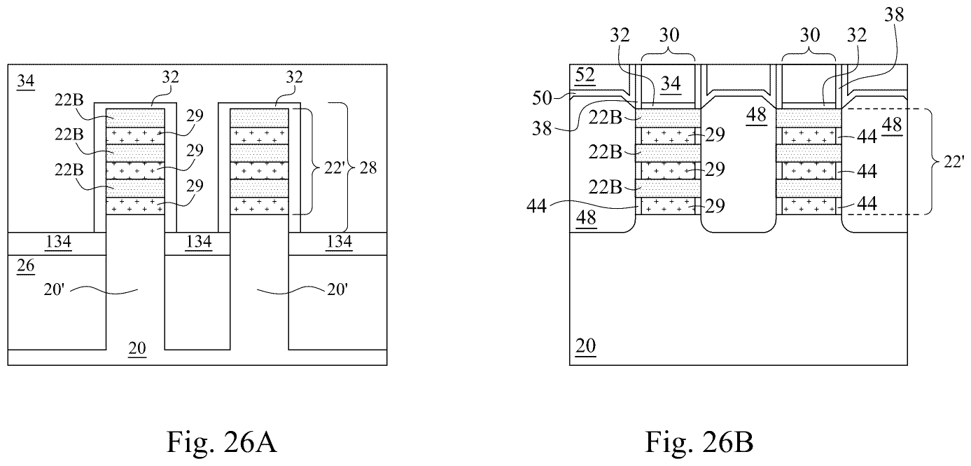

FIGS. 26A and 26B illustrate the cross-sectional views of the structure after the formation of Contact Etch Stop Layer (CESL) 50 and Inter-Layer Dielectric (ILD) 52. FIGS. 26A and 26B illustrate the cross-sections A2-A2 and B-B, respectively, in FIG. 21. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may include silicon oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIGS. 26A and 26B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

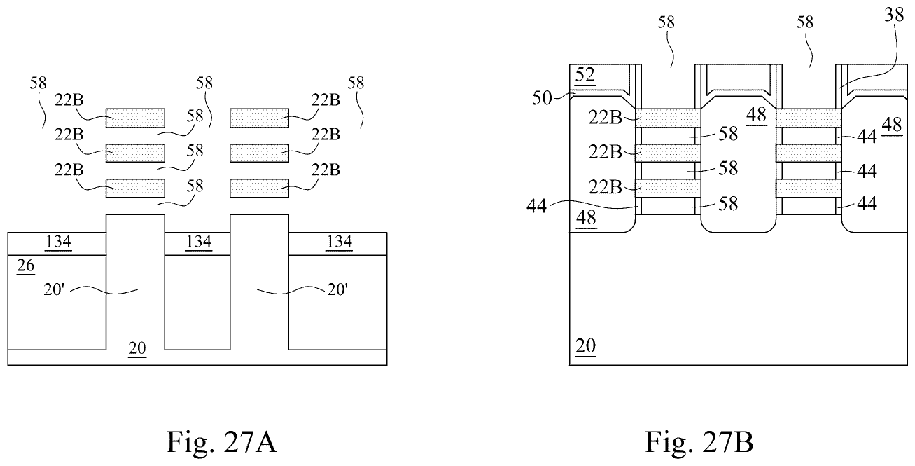

Next, dummy gate electrodes 34 and dummy gate dielectrics 32 (and hard masks 36, if remaining) are removed in one or more etching processes, so that recesses 58 are formed, as shown in FIGS. 27A and 27B. The respective process is illustrated as process 232 in the process flow 200 as shown in FIG. 31. In accordance with some embodiments, dummy gate electrodes 34 and dummy gate dielectrics 32 are removed through an anisotropic dry etching process(es). For example, the etching process may be performed using reaction gas(es) that selectively etch dummy gate electrodes 34 and dummy gate dielectrics 32 at faster rates than ILD 52. Each recess 58 exposes and/or overlies portions of nanostructures 22B, which include the future channel regions in subsequently completed transistors.

Disposable interposers 29 are then removed to extend recesses 58 between nanostructures 22B. The respective process is illustrated as process 234 in the process flow 200 as shown in FIG. 31. The corresponding process is also referred to as a sheet formation process. Disposable interposers 29 may be removed by performing an isotropic etching process such as a wet etching process using etchants that are selective to the materials of disposable interposers 29, while nanostructures 22B and substrate 20 remain relatively un-etched as compared to disposable interposers 29.

In accordance with some embodiments in which disposable interposers 29 include, for example, silicon oxide, the mixture of NF₃ and NH₃, the mixture of HF and NH₃, or a diluted HF solution may be used to remove disposable interposers 29.

In the etching of disposable interposers 29, the STI regions 26 are protected from the etching chemical by hard masks 134 due to the high etching selectivity, which is the ratio of the etching rate of disposable interposers 29 to the etching rate of the hard masks 134.

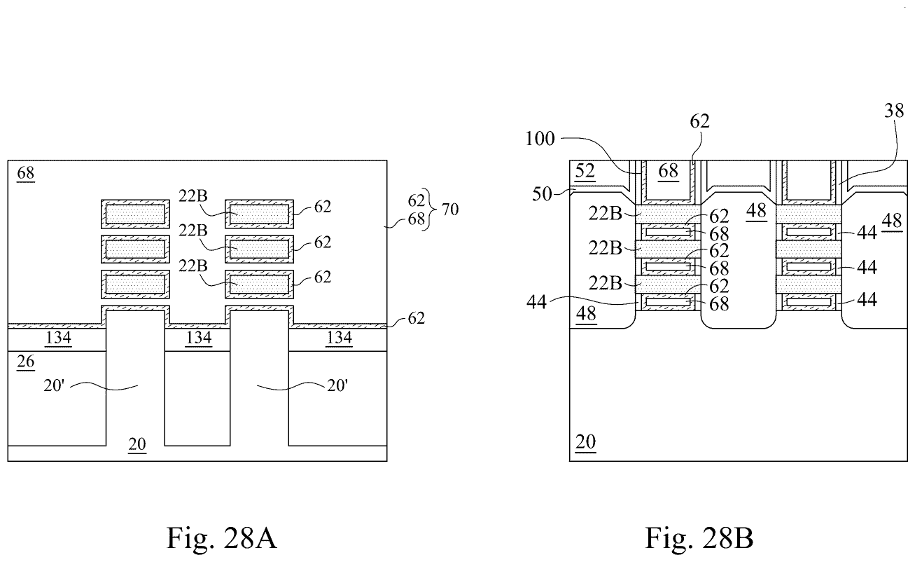

Referring to FIGS. 28A and 28B, gate dielectrics 62 and gate electrodes 68 are formed, hence forming replacement gate stacks 70. The respective process is illustrated as process 236 in the process flow 200 as shown in FIG. 31. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process.

In accordance with some embodiments, the high-k dielectric layers comprise one or more high-k dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′.

After the filling of recesses 58, a planarization process such as a CMP process or a mechanical grinding process is performed to remove the excess portions of the gate dielectrics 62 and gate electrodes 68, which excess portions are over the top surface of ILD 52. Gate electrodes 68 and gate dielectrics 62 are collectively referred to as gate stacks 70 of the resulting transistors.

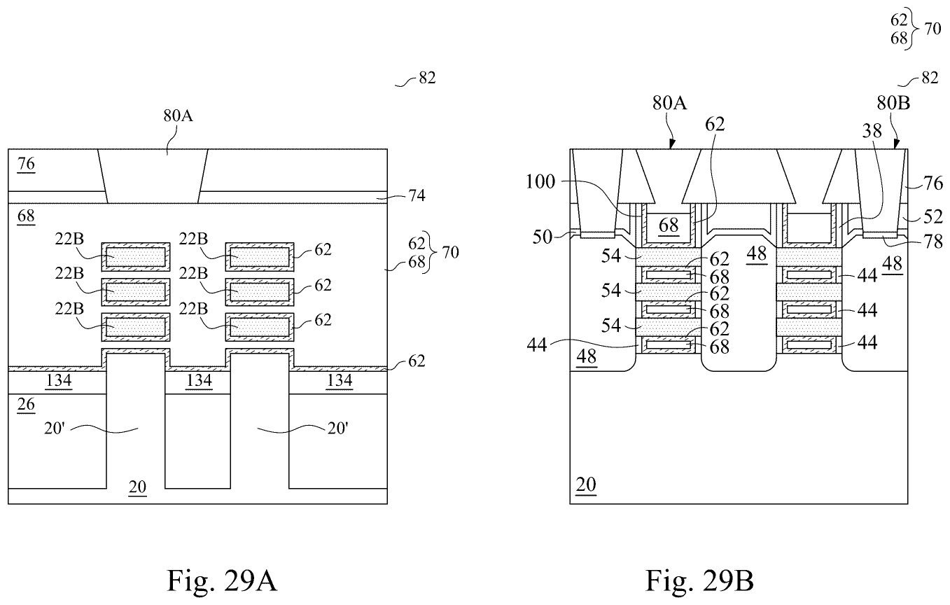

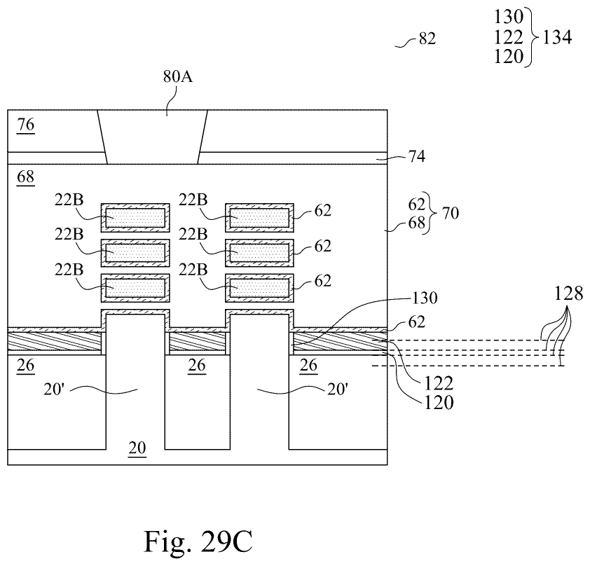

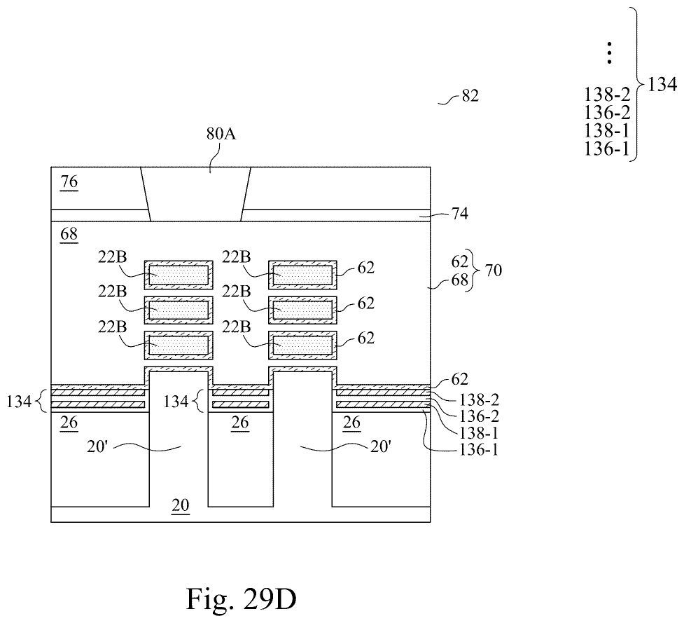

In the processes shown in FIGS. 29A and 29B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 29A and 29B, ILD 76 is deposited over ILD 52 and over gate masks 74. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

ILD 76, ILD 52, CESL 50, and gate masks 74 are then etched to form recesses (occupied by contact plugs 80A and 80B) exposing surfaces of source/drain regions 48 and/or gate stacks 70. Although FIGS. 29B illustrates that contact plugs 80A and 80B are in a same cross-section, in various embodiments, contact plugs 80A and 80B may be formed in different cross-sections, thereby reducing the risk of shorting with each other.

Silicide regions 78 are formed over source/drain regions 48. Contact plugs 80B are formed over silicide regions 78. Also, contacts 80A (may also be referred to as gate contact plugs) are also formed in the recesses, and are over and contacting gate electrodes 68. The corresponding structure is also shown in FIG. 29A. Transistor 82 is thus formed.

FIGS. 29C illustrates the structure shown in FIG. 29A, wherein the details of composite hard masks 134 having the structure as shown in FIG. 8 are illustrated. The composite hard masks 134 in accordance with these embodiments include hard masks 122′and 130, and may include dielectric layer 120, which may be, or may not be, distinguishable from the underlying STI regions 26. It is noted that the bottoms of hard mask layer 130 may be at any of the levels 128. Also, the dielectric layer 120 may or may not include sidewall portions between semiconductor strips 20′ and hard masks 122′.

FIGS. 29D illustrates the structure shown in FIG. 29A, wherein the details of the composite hard masks 134 having the structure as shown in FIG. 20 are illustrated. The composite hard masks 134 in accordance with these embodiments include a plurality of hard mask layers 138 and a plurality of dielectric layers 136 located alternatingly. The number of hard mask layers 138 may be the same as shown in FIG. 20, or fewer than what is shown in FIG. 20 due to the loss of hard mask layers 138, wherein the loss may occur during the removal of disposable interposers 29.

The embodiments of the present disclosure have some advantageous features. By forming hard masks to protect the STI regions, the loss of STI regions in the sheet formation process (the removal of the disposable interposers) may be eliminated. The hard masks may have various structures formed using different methods.

In accordance with some embodiments of the present disclosure, a method comprises forming a shallow trench isolation region aside of a protruding fin; forming a composite hard mask over the shallow trench isolation region, wherein the forming the composite hard mask comprises a plurality of deposition processes and a plurality of etching processes; forming a dummy gate stack over the protruding fin; removing a sacrificial layer in the protruding fin to leave a space between a first semiconductor nanostructure and a second semiconductor nanostructure that are in the protruding fin; forming a disposable interposer in the space; removing the dummy gate stack; removing the disposable interposer using an etching chemical, wherein when the disposable interposer is removed, the composite hard mask is exposed to the etching chemical, and a bottom portion of the composite hard mask remains after the disposable interposer is removed; and forming a gate stack, wherein a portion of the gate stack is filled in the space.

In an embodiment, the forming the composite hard mask comprises depositing an etch stop layer on the protruding fin; forming a first hard mask layer on the etch stop layer and at a bottom of a trench aside of the protruding fin; etching the etch stop layer to leave a recess between the protruding fin and the first hard mask layer; and forming a second hard mask layer to fill the recess. In an embodiment, the forming the second hard mask layer comprises depositing a blanket hard mask layer comprising a first portion on the protruding fin and a second portion filling the recess; and etching the first portion, wherein the second portion is left in the recess.

In an embodiment, the forming the composite hard mask comprises forming a first dielectric layer at a bottom of a trench aside of the protruding fin; forming a first hard mask layer over the first dielectric layer; forming a second dielectric layer over the first hard mask layer; and forming a second hard mask layer over the second dielectric layer. In an embodiment, the first dielectric layer and the first hard mask layer are formed by processes comprising depositing the first dielectric layer comprising a top portion on a top surface and a first sidewall portion on a sidewall of the protruding fin; depositing the first hard mask layer, wherein the first hard mask layer comprises a second sidewall portion comprising discrete islands; and removing the first sidewall portion of the first dielectric layer.

In an embodiment, the composite hard mask comprises a first sidewall physically contacting a second sidewall of the protruding fin. In an embodiment, the composite hard mask comprises a first dielectric material; and a second dielectric material contacting opposing sidewall of the first dielectric material, wherein the first dielectric material is different from the first dielectric material. In an embodiment, the composite hard mask comprises a first dielectric material; and a second dielectric material contacting opposing sidewall of the first dielectric material, wherein the second dielectric material is same as the first dielectric material.

In an embodiment, the forming the disposable interposer comprising depositing a silicon oxide layer; and performing an etching process on the silicon oxide layer. In an embodiment, when the disposable interposer is etched, the shallow trench isolation region is separated from the etching chemical by the bottom portion of the composite hard mask.

In accordance with some embodiments of the present disclosure, a structure comprises a semiconductor strip; a first semiconductor nanostructure overlapping, and spaced apart from, the semiconductor strip; a shallow trench isolation region contacting an edge of the semiconductor strip; a gate stack comprising a first portion underlying the first semiconductor nanostructure and overlying the semiconductor strip; and a hard mask overlying the shallow trench isolation region and underlying a second portion of the gate stack, wherein the hard mask comprises a first hard mask layer comprising a first sidewall; and a second hard mask layer comprising a second sidewall contacting the first sidewall to form an interface; and a third sidewall opposing to the second sidewall, wherein the third sidewall contacts the semiconductor strip.

In an embodiment, the first hard mask layer and the second hard mask layer comprise a same dielectric material. In an embodiment, wherein both of the first hard mask layer and the second hard mask layer comprise silicon nitride. In an embodiment, the structure further comprises a dielectric layer underlying the first hard mask layer and overlying the shallow trench isolation region. In an embodiment, a first bottom of the first hard mask layer is higher than or lower than a second bottom of the second hard mask layer.

In an embodiment, the structure further comprises a second semiconductor nanostructure overlapping, and spaced apart from, the first semiconductor nanostructure, wherein the gate stack further comprises a third portion between the first semiconductor nanostructure and the second semiconductor nanostructure.

In accordance with some embodiments of the present disclosure, a structure comprises a semiconductor substrate; a shallow trench isolation region in the semiconductor substrate, wherein a portion of the semiconductor substrate is aside of and contacting the shallow trench isolation region to act as a semiconductor strip; a dielectric hard mask over the shallow trench isolation region, wherein the dielectric hard mask comprises a first portion; and a second portion and a third portion contacting opposing sidewalls of the first portion, wherein a first bottom surface of the first portion is higher than or lower than a second bottom surface of the second portion; and a gate stack over and contacting the dielectric hard mask.

In an embodiment, the first bottom surface of the first portion is higher than the second bottom surface of the second portion. In an embodiment, the first bottom surface of the first portion is lower than the second bottom surface of the second portion. In an embodiment, the structure further comprises a dielectric layer underlying and physically contacting the first portion of the dielectric hard mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. (canceled)

2. A method comprising:
forming a shallow trench isolation region aside of a protruding fin, wherein the shallow trench isolation region comprises a first material, and wherein the protruding fin comprises a first semiconductor nanostructure and a second semiconductor nanostructure;
forming a composite hard mask over the shallow trench isolation region, wherein the forming the composite hard mask comprises a cycle comprising:
forming a first hard mask layer over the shallow trench isolation region; and
forming a second hard mask layer over the first hard mask layer, wherein the second hard mask layer comprises a second material different from the first material;
forming a dummy gate stack over the protruding fin; and
removing a disposable interposer using an etching chemical, wherein the disposable interposer is between the first semiconductor nanostructure and the second semiconductor nanostructure, and wherein during the removing the disposable interposer, the second material is exposed to the etching chemical.

3. The method of claim 2, wherein the first hard mask layer comprises a third material different from the second material.

4. The method of claim 3, wherein the the third material is same as the first material.

5. The method of claim 3, wherein the first material comprises silicon oxide, and the second material comprises silicon nitride.

6. The method of claim 2 further comprising forming a replacement gate stack, wherein a portion of the replacement gate stack is formed in a space left by the disposable interposer.

7. The method of claim 6, wherein at a time after the replacement gate stack is formed, both of the first hard mask layer and the second hard mask layer remain over the shallow trench isolation region.

8. The method of claim 2 further comprising:
removing a sacrificial layer in the protruding fin to leave a space between the first semiconductor nanostructure and the second semiconductor nanostructure; and
forming the disposable interposer in the space.

9. The method of claim 2, wherein at least a bottom portion of the composite hard mask remains after the disposable interposer is removed.

10. The method of claim 2, wherein the forming the composite hard mask further comprises repeating the cycle to form:
a third hard mask layer over the second hard mask layer; and
a fourth hard mask layer over the third hard mask layer.

11. The method of claim 10, wherein the third hard mask layer comprises a same material as the first hard mask layer, and the fourth hard mask layer comprises an additional same material as the second hard mask layer.

12. The method of claim 2, wherein the forming the second hard mask layer comprises a non-conformal deposition process, so that a top portion of the second hard mask layer is thicker than a sidewall portion of the second hard mask layer.

13. The method of claim 12, wherein the forming the first hard mask layer comprises a conformal deposition process.

14. A method comprising:
forming a shallow trench isolation region aside of and contacting a semiconductor strip;
forming a semiconductor nanostructure overlapping, and spaced apart from, the semiconductor strip;
forming a plurality of cycles to form a composite hard mask, the plurality of cycles comprising:
forming a first plurality of hard mask layers comprising a first dielectric material; and
forming a second plurality of hard mask layers, with the first plurality of hard mask layers and the second plurality of hard mask layers being located alternatingly, wherein the second plurality of hard mask layers comprise a second dielectric material different from the first dielectric material; and
forming a gate stack extending into a space between the semiconductor strip and the semiconductor nanostructure, wherein the gate stack overlaps at least a portion of the composite hard mask.

15. The method of claim 14, wherein the forming the second plurality of hard mask layers comprises depositing the second plurality of hard mask layers through non-conformal deposition processes.

16. The method of claim 14, wherein the forming the second plurality of hard mask layers comprises depositing the second plurality of hard mask layers as comprising:
continuous horizontal portions over the semiconductor nanostructure; and
discontinuous sidewall portions aside of the semiconductor nanostructure.

17. The method of claim 14, wherein the gate stack physically contacts the composite hard mask.

18. The method of claim 14 further comprising removing a disposable interposer between the semiconductor nanostructure and the semiconductor strip, wherein at a time after the disposable interposer is removed, at least one of the first plurality of hard mask layers and at least one of the second plurality of hard mask layers remain.

19. A method comprising:
forming a shallow trench isolation region in a semiconductor substrate, wherein the shallow trench isolation region comprises a first dielectric material, and the shallow trench isolation region is aside of a protruding fin;
forming a first plurality of dielectric hard mask layers over the shallow trench isolation region, wherein the first plurality of dielectric hard mask layers are stacked and are separate from each other, and wherein the first plurality of dielectric hard mask layers comprise a second dielectric material different from the first dielectric material;
replacing sacrificial layers in the protruding fin with disposable interposers;
removing the disposable interposers to form lateral recesses, wherein at a time when the disposable interposers are removed, the first plurality of dielectric hard mask layers main to overlap the shallow trench isolation region; and
forming a gate stack in the lateral recesses.

20. The method of claim 19 further comprising forming a second plurality of dielectric hard mask layers between the first plurality of dielectric hard mask layers, wherein the second plurality of dielectric hard mask layers comprise the first dielectric material.

21. The method of claim 19, wherein the first plurality of dielectric hard mask layers are laterally spaced apart from the protruding fin.
